(19) United States
(12) Patent Application Publication
(10) Pub. No.: US 2004/0266155 A1
(43) Pub. Date: Dec. 30, 2004

(54) Formation of small gates beyond lithographic limits

(75) Inventors: Chew Hoe Ang, Singapore (SG); Eng Hua Lim, Singapore (SG); Randall Cher Liang Cha, Singapore (SG); Jia Zhen Zheng, Singapore (SG); Elgin Quek, Singapore (SG); Mei Sheng Zhou, Singapore (SG); Daniel Yen, Singapore (SG)

Correspondence Address: STEPHEN B. ACKERMAN, 28 DAVIS AVENUE, POUGHKEEPSIE, NY, 12603, US

(73) Assignee: Chartered Semiconductor Manufacturing Ltd.

(21) Appl. No.: 10/610,047

(22) Filed: Jun. 30, 2003

(51) Int. Cl. H01L 21/4763; H01L 21/8242; H01L 21/336; H01L 21/3205

(52) U.S. Cl. 438/595; 438/585; 438/299; 438/253

(57) ABSTRACT

A method of fabricating an ultra-small semiconductor structure comprising the following steps. A substrate having a lower dielectric layer and an overlying upper dielectric layer formed thereover is provided. Using a lithography process having a lithography limit, the upper dielectric layer is patterned to form a first opening exposing a portion of the lower dielectric layer. The first opening having exposed side walls and a width equal to the lithography limit. Sidewall spacers having a lower width are formed over the exposed side walls of the first opening. Using the sidewall spacers as masks, the lower dielectric layer is patterned to form a lower opening having a width less than the first opening width. The patterned upper dielectric layer is removed. An ultra-small semiconductor structure is formed within the lower opening. The ultra-small semiconductor structure having a width equal to the lithography limit minus twice the lower width of the sidewall spacer.

### FIELD OF THE INVENTION

The present invention relates generally to fabrication of semiconductor devices, and more specifically to methods of fabricating semiconductor gates/structures.

### BACKGROUND OF THE INVENTION

Smaller design rules require methods to fabricate smaller semiconductor gates and structures.

U.S. Pat. No. 4,022,932 to Feng describes a resist reflow method for making submicron patterned resist masks.

U.S. Pat. No. 5,899,746 to Mukai describes a method for making small patterns by eroding a photoresist pattern.

U.S. Pat. No. 4,824,747 to Andrews describes a method for forming a variable width channel.

U.S. Pat. No. 4,449,287 to Maas et al. describes a method of providing a narrow groove or slot in a substrate region.

U.S. Pat. No. 4,546,066 to Field et al. describes a method for forming narrow images on semiconductor substrates.

### SUMMARY OF THE INVENTION

Accordingly, it is an object of one or more embodiments of the present invention to provide an improved method of fabricating ultra-small semiconductor gates.

Other objects will appear hereinafter.

It has now been discovered that the above and other objects of the present invention may be accomplished in the following manner. Specifically, a substrate having a lower dielectric layer and an overlying upper dielectric layer formed thereover is provided. Using a lithography process having a lithography limit, the upper dielectric layer is patterned to form a first opening exposing a portion of the lower dielectric layer. The first opening having exposed side walls and a width equal to the lithography limit. Sidewall spacers having a lower width are formed over the exposed side walls of the first opening. Using the sidewall spacers as masks, the lower dielectric layer is patterned to form a lower opening having a width less than the first opening width. The patterned upper dielectric layer is removed. An ultra-small semiconductor structure is formed within the lower opening. The ultra-small semiconductor structure having a width equal to the lithography limit minus twice the lower width of the sidewall spacer.

### BRIEF DESCRIPTION OF THE DRAWINGS

The features and advantages of the present invention will be more clearly understood from the following description taken in conjunction with the accompanying drawings in which like reference numerals designate similar or corresponding elements, regions and portions and in which:

FIGS. 1 to 6 schematically illustrate in cross-sectional representation a preferred embodiment of the present invention.

### DETAILED DESCRIPTION OF THE PREFERRED EMBODIMENTS

Initial Structure

FIG. 1 illustrates a cross-sectional view of a substrate 8, preferably a semiconductor substrate comprised of silicon (Si) or germanium (Ge) and is more preferably comprised of silicon.

A first dielectric layer 10 is formed over substrate 10 to a thickness of preferably from about 500 to 3000 Å and more preferably from about 500 to 1000 Å. First dielectric layer 10 is preferably formed by chemical vapor deposition (CVD) is preferably comprised of silicon dioxide (SiO₂).

An etch stop layer 12 is preferably formed over the first dielectric layer 10 to a thickness of preferably from about 300 to 800 Å and more preferably from about 300 to 500 Å. Etch stop layer 12 is preferably comprised of silicon nitride (Si₃N₄), silicon oxynitride (SiON) or silicon germanium (SiGe) and is more preferably silicon germanium (SiGe).

A second dielectric layer 14 is formed over etch stop layer 12 to a thickness of preferably from about 500 to 3000 Å and more preferably from about 500 to 1000 Å. Second dielectric layer 14 is preferably formed by chemical vapor deposition (CVD) is preferably comprised of polysilicon or amorphous silicon and is more preferably polysilicon.

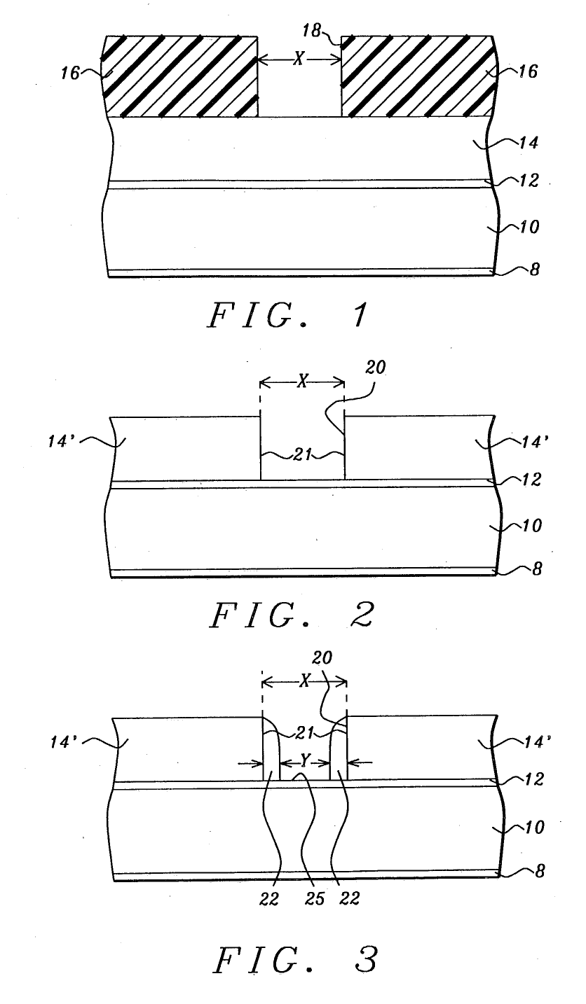

To pattern second dielectric layer 14 at the lithography limit (as shown in FIG. 2 described below), a patterned mask layer 16 having opening 18 with a width X (substantially equal to the lithography limit) may be formed over second dielectric layer 14. Patterned mask layer 16 is preferably comprised of photoresist.

Patterning of Second Dielectric Layer 14

As shown in FIG. 2, second dielectric layer 14 is patterned to form opening 20 having width X substantially equal to the lithography limit used to pattern second dielectric layer 14. Opening 20 has exposed side walls 21.

Currently, X is preferably from about 50 to 500 nm and more preferably from about 100 to 300 nm.

Second dielectric layer 14 may be patterned using an overlying patterned mask layer 16 (see FIG. 1), for example a patterned photoresist layer 16 as shown in FIG. 1.

If used, patterned mask layer 16 is removed from patterned second dielectric layer 14′ and the structure may be cleaned as necessary.

Formation of Spacers 22

As shown in FIG. 3, spacer material is then deposited within opening 20 and etched to form sidewall spacers 22 overlying side walls 21. Sidewall spacers 22 each have a lower width Y that is preferably from about 5 to 20 nm and more preferably from about 5 to 10 nm.

Sidewall spacers 22 are preferably comprised of silicon nitride (Si₃N₄), Al₂O₃ or silicon oxynitride (SiON) and are more preferably silicon nitride (Si₃N₄). Sidewall spacers 22 must be comprised of a different material than that comprising etch stop layer 12 with a good etch sensitivity.

A portion 25 of etch stop layer 12 within opening 20 and not covered by sidewall spacers 22 is left exposed. The width of exposed portion 25 of etch stop layer 12 is equal to X−2Y.

Patterning of Exposed Portion 25 of Etch Stop Layer 12 and Underlying First Dielectric Layer 10

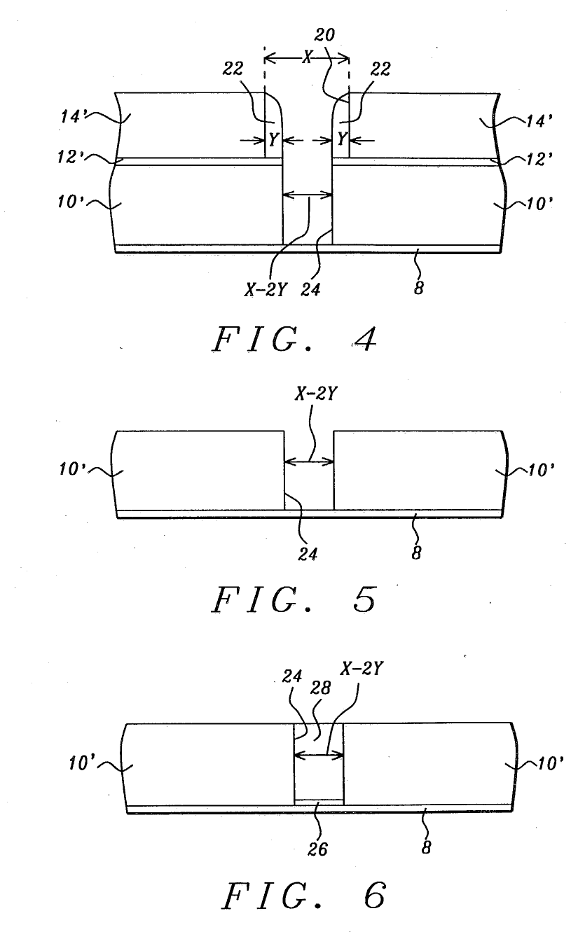

As shown in FIG. 4, using, inter alia, sidewall spacers 22 as a hard mask, the exposed portion 25 of etch stop layer 12 and the underlying first dielectric layer 10 are etched to form gate opening 24 within patterned first dielectric layer 10′. Since the first dielectric layer 10 is more preferably comprised of SiO₂ and the second dielectric layer 14 is more preferably comprised of polysilicon, the second dielectric layer 14 is not appreciably etched during this step due to the difference in etch sensitivity.

Gate opening 24 within patterned first dielectric layer 10′ has a width equal to X−2Y, that is, the lithography limit (X) less twice the lower width of one sidewall spacer 22.

Removal of Sidewall Spacers 22, Patterned Second Dielectric Layer 14′ and Patterned Etch Stop Layer 12′

As shown in FIG. 5, sidewall spacers 22, patterned second dielectric layer 14′ and patterned etch stop layer 12′ are removed from patterned first dielectric layer 10′ and the structure is cleaned as necessary. These structures 22, 14′, 10′ may be removed in separate steps. For example, patterned second dielectric layer 14′ (polysilicon) may be removed using hot KOH, sidewall spacers 22 (Si₃N₄) may be removed using hot phosphoric acid and the patterned etch stop layer 12′ (SiGe) may be removed using TMAH.(

Formation of Gate Structure 28

As shown in FIG. 6, a thin gate dielectric layer 26 is grown over substrate 8 within gate opening 24 to a thickness of preferably from about 8 to 100 Å and more preferably from about 8 to 20 Å.

Gate material is then formed over patterned first dielectric layer 10′ and over gate dielectric layer 26, filling gate opening 24. The gate material is then planarized to remove the excess of the gate material from over patterned first dielectric layer 10′ and forming a planarized damascene ultra-small gate structure 28 within gate opening 24.

Gate structure 28 has a width of X−2Y, that is less than the lithography limit (X) by twice the lower width (Y) of the sidewall spacers 22 used as hard masks to pattern gate opening 24. Currently, the width of gate structure 28 may be a narrow as from about 20 to 50 nm. As the limits of lithography decrease, the width of gate structure 28 may also narrow by using the method of the present invention.

The method of the present invention may be used by one skilled in the art to form other ultra-small semiconductor structures besides gate structures 28.

Advantages of the Invention

The advantages of one or more embodiments of the present invention include:

1) forming ultra small gates beyond the photolithographic limit; and

2) forming planarized gates having reduced topography.

While particular embodiments of the present invention have been illustrated and described, it is not intended to limit the invention, except as defined by the following claims.

We claim:

1. A method of fabricating an ultra-small semiconductor structure, comprising the steps of:
providing a substrate having a lower dielectric layer and an overlying upper dielectric layer formed thereover;
using a lithography process to pattern the upper dielectric layer to form a first opening exposing a portion of the lower dielectric layer; the first opening having exposed side walls; the lithography process having a lithography limit; the first opening having a width X equal to the lithography limit;
forming sidewall spacers over the exposed side walls of the first opening; the sidewall spacers having a lower width Y;
patterning the lower dielectric layer to form a lower opening having a width less than the first opening width X by using the sidewall spacers as masks;
removing the patterned upper dielectric layer; and
forming an ultra-small semiconductor structure within the lower opening; the ultra-small semiconductor structure having a width equal to the lithography limit minus twice the lower width of the sidewall spacer.

2. The method of claim 1, wherein the substrate is comprised of silicon or germanium, the lower dielectric layer is comprised of silicon dioxide; and the upper dielectric layer is comprised of a material selected from the group consisting of polysilicon and amorphous silicon.

3. The method of claim 1, wherein the substrate is comprised of silicon, the lower dielectric layer is comprised of silicon dioxide and the upper dielectric layer is comprised of polysilicon.

4. The method of claim 1, wherein the sidewall spacers are comprised of a material selected from the group consisting of silicon nitride, Al₂O₃ and silicon oxynitride.

5. The method of claim 1, wherein the sidewall spacers are comprised of silicon nitride.

6. The method of claim 1, wherein the width X of first opening is from about 50 to 500 nm.

7. The method of claim 1, wherein the width X of first opening is from about 100 to 300 nm.

8. The method of claim 1, wherein the lower width Y of sidewall spacers is from about 5 to 20 nm.

9. The method of claim 1, wherein the lower width Y of sidewall spacers is from about 5 to 10 nm.

10. The method of claim 1, wherein the width of the ultra-small semiconductor structure is from about 20 to 50 nm.

11. The method of claim 1, wherein the lower and upper dielectric layers are comprised of chemical vapor deposition dielectric materials.

12. The method of claim 1, wherein an etch stop layer is interposed between the lower and upper dielectric layers.

13. The method of claim 1, wherein an etch stop layer is interposed between the lower and upper dielectric layers; the etch stop layer being comprised of a material selected from the group consisting of silicon nitride, silicon oxynitride and silicon germanium.

14. The method of claim 1, wherein an etch stop layer is interposed between the lower and upper dielectric layers; the etch stop layer being comprised of silicon germanium.

15. The method of claim 1, wherein the ultra-small semiconductor structure is a gate structure.

16. A method of fabricating an ultra-small semiconductor structure, comprising the steps of:
providing a substrate having a lower dielectric layer formed thereover;
forming an etch stop layer over the lower dielectric layer;
forming an upper dielectric layer over the etch stop layer;
using a lithography process to pattern the upper dielectric layer to form a first opening exposing a portion of the etch stop layer; the first opening having exposed side walls; the lithography process having a lithography limit; the first opening having a width equal to the lithography limit;
forming sidewall spacers over the exposed side walls of the first opening; the sidewall spacers having a lower width;
patterning the exposed etch stop layer portion and the underlying lower dielectric layer to form a lower opening having a width less than the first opening width by using the sidewall spacers as masks;
removing the sidewall spacers, the upper dielectric layer and the etch stop layer; and
forming an ultra-small semiconductor structure within the lower opening; the ultra-small semiconductor structure having a width equal to the lithography limit minus twice the lower width of the sidewall spacer.

17. The method of claim 16, wherein the substrate is comprised of a material selected from the group consisting of silicon and germanium.

18. The method of claim 16, wherein the substrate is comprised of silicon.

19. The method of claim 16, wherein the lower dielectric layer is comprised of silicon dioxide; and the upper dielectric layer is comprised of a material selected from the group consisting of polysilicon and amorphous silicon.

20. The method of claim 16, wherein the lower dielectric layer is comprised of silicon dioxide and the upper dielectric layer is comprised of polysilicon.

21. The method of claim 16, wherein the etch stop layer is comprised of a material selected from the group consisting of silicon nitride, silicon oxynitride and silicon germanium.

22. The method of claim 16, wherein the etch stop layer is comprised of silicon germanium.

23. The method of claim 16, wherein the sidewall spacers are comprised of a material selected from the group consisting of silicon nitride, Al₂O₃ and silicon oxynitride.

24. The method of claim 16, wherein the sidewall spacers are comprised of silicon nitride.

25. The method of claim 16, wherein the width of the first opening is from about 50 to 500 nm.

26. The method of claim 16, wherein the width of the first opening is from about 100 to 300 nm.

27. The method of claim 16, wherein the lower width of the sidewall spacers is from about 5 to 20 nm.

28. The method of claim 16, wherein the lower width of sidewall spacers is from about 5 to 10 nm.

29. The method of claim 16, wherein the width of the ultra-small semiconductor structure is from about 20 to 50 nmÅ.

30. The method of claim 16, wherein the lower and upper dielectric layers are comprised of chemical vapor deposition dielectric materials.

31. The method of claim 16, wherein the ultra-small semiconductor structure is a gate structure.

32. A method of fabricating an ultra-small semiconductor structure, comprising the steps of:
providing a silicon substrate having a lower CVD dielectric layer formed thereover;
forming an etch stop layer over the lower CVD dielectric layer;
forming an upper CVD dielectric layer over the etch stop layer;
using a lithography process to pattern the upper CVD dielectric layer to form a first opening exposing a portion of the etch stop layer; the first opening having exposed side walls; the lithography process having a lithography limit; the first opening having a width equal to the lithography limit;
forming sidewall spacers over the exposed side walls of the first opening; the sidewall spacers having a lower width;
patterning the exposed etch stop layer portion and the underlying lower CVD dielectric layer to form a lower opening having a width less than the first opening width by using the sidewall spacers as masks;
removing the sidewall spacers, the upper CVD dielectric layer and the etch stop layer; and
forming an ultra-small semiconductor structure within the lower opening; the ultra-small semiconductor structure having a width equal to the lithography limit minus twice the lower width of the sidewall spacer.

33. The method of claim 32, wherein the lower CVD dielectric layer is comprised of silicon dioxide; and the upper CVD dielectric layer is comprised of a material selected from the group consisting of polysilicon and amorphous silicon.

34. The method of claim 32, wherein the lower CVD dielectric layer is comprised of silicon dioxide and the upper CVD dielectric layer is comprised of polysilicon.

35. The method of claim 32, wherein the etch stop layer is comprised of a material selected from the group consisting of silicon nitride, silicon oxynitride and silicon germanium.

36. The method of claim 32, wherein the etch stop layer is comprised of silicon germanium.

37. The method of claim 32, wherein the sidewall spacers are comprised of a material selected from the group consisting of silicon nitride, Al₂O₃ and silicon oxynitride.

38. The method of claim 32, wherein the sidewall spacers are comprised of silicon nitride.

39. The method of claim 32, wherein the width of first opening is from about 50 to 500 nm.

40. The method of claim 32, wherein the width of first opening is from about 100 to 300 nm.

41. The method of claim 32, wherein the lower width of sidewall spacers is from about 5 to 20 nm.

42. The method of claim 32, wherein the lower width of sidewall spacers is from about 5 to 10 nm.

43. The method of claim 32, wherein the width of the ultra-small semiconductor structure 28 is from about 20 to 50 nm.

44. The method of claim 32, wherein the ultra-small semiconductor structure is a gate structure.
